(19) United States
(12) Patent Application Publication
(10) Pub. No.: US 2025/0030218 A1
(43) Pub. Date: Jan. 23, 2025

(54) OPTICAL DEVICE HAVING SELF-HERMETIC COATING AND METHOD OF FABRICATING THE SAME

(71) Applicant: Source Photonics Taiwan, Inc., HSINCHU (TW)

(72) Inventors: HORNG-SHYANG CHEN, HSINCHU COUNTY (TW); THANT ZIN, HSINCHU CITY (TW); HSUYING CHEN, HSINCHU CITY (TW); CHUN-KO CHEN, HSINCHU COUNTY (TW); CHIEN-KAI WANG, YILAN COUNTY (TW); HAO-HSIANG TANG, HSINCHU COUNTY (TW); NI YEH WU, HSINCHU CITY (TW); SHIN-YI SHEN, HSINCHU (TW); RUEI-MING YANG, HSINCHU CITY (TW)

(21) Appl. No.: 18/769,159

(22) Filed: Jul. 10, 2024

(30) Foreign Application Priority Data
Jul. 17, 2023 (TW) 112126616

(51) Int. Cl. H01S 5/00; H01S 5/028; H01S 5/042

(52) U.S. Cl. CPC H01S 5/0064; H01S 5/028; H01S 5/04256

(57) ABSTRACT

The present application provides an optical device and a method of fabricating the same. The optical device include a semiconductor stack structure, an anti-reflective film and a highly-reflective film. The semiconductor stack structure is configured to generate a laser beam and emit the laser beam from its front facet while receiving an electric current. The anti-reflective film is disposed on the front facet of the semiconductor stack structure and configured to increase the transmittance (reduce a reflectivity) of the front facet to the laser beam. The highly-reflective film is disposed on a rear facet of the semiconductor stack structure and is configured to reduce a loss (increase a reflectivity) of the laser beam transmitted to the rear facet. The anti-reflective film and the highly-reflective film respectively have refractive indices greater than 2, and the highly-reflective film has a thickness greater than that of the anti-reflective film.

### CROSS-REFERENCE TO RELATED APPLICATIONS

This application claims the benefits of Taiwan Patent Application No. 112126616, filed on Jul. 17, 2023, which is hereby incorporated herein by reference in its entirety.

### TECHNICAL FIELD

The present application relates to an optical device and a method for fabricating the same; in particular, to a semiconductor laser component with a sealing coating to prevent moisture penetration and a method for fabricating the same.

### BACKGROUND

Semiconductor lasers (or laser diodes) are widely used in optical communication systems because of their small size, low power consumption, fast response, shock resistance, long life, high efficiency and low price. In urban areas, optical communication systems are often installed in underground conduits; in order to minimize the optical performance of the laser diode from being affected by the high-temperature and high-humidity environment in the underground conduits, the laser diode chip is usually hermetically sealed with the package housing 10 shown in FIG. 1 and FIG. 2 to prevent the moisture in the environment from entering the laser diode.

Reference is made to FIG. 1 and FIG. 2, wherein FIG. 1 is a cross-sectional view of a package housing 10 of a conventional semiconductor laser, and FIG. 2 is an elevation view of the package housing 10 of the semiconductor laser. The package housing 10 includes a base 110, a plurality of pins 120, a cylindrical cover 130, and a lens 140; the base 110 can be made of metal or ceramic material, the pins 120 penetrate through the upper and lower surfaces of the base 110, and an insulating layer 150 can be annularly located between the base 110 and each of the pins 120 to insulate the base 10 from the electrical conductivity of each of the pins 120. A laser diode chip (not shown) is mounted on the base 110 and electrically connected to the pins 120. The cylindrical cover 130 is a hermetic sealing cover which is combined with the base 110 to hermetically seal the laser diode chip to improve the moisture and interference resistance of the laser diode chip. The lens 140 is located on the top of the cylindrical cover 130, and is configured to focus or collimate the laser beam emitted from the laser diode chip, which is then emitted into the optical fiber of the optical communication system.

However, the use of the package housing 10 not only increases the cost of the optical communication system, but also increases the difficulty of assembling the cylindrical cover 130 with the base 110 due to the very high mounting alignment requirements of the lens 140 and the laser diode wafer.

The foregoing “Background” section is provided for background information only and is not intended to be used as an admission that the subject matter disclosed in the foregoing “Background” section constitutes prior art, and no part in the foregoing “Background” section is intended to be used to as an admission that that any part of the present disclosure (including the foregoing “Background” section) constitutes prior art of the present disclosure.

### SUMMARY OF THE INVENTION

One aspect of the present disclosure provides an optical device, which includes a semiconductor stack structure, an anti-reflective film and a highly-reflective film. The semiconductor stack structure is configured to generate a laser beam when receiving a current, and emit the laser beam from a front facet of the semiconductor stack structure, wherein the front facet is a lateral side of the semiconductor stack structure; the anti-reflective film is disposed on the front facet, and is configured to increase the transmittance of the laser beam; the highly-reflective film is disposed on a rear facet of the semiconductor stack structure, wherein the rear facet is another lateral side of the semiconductor stack structure, and the highly-reflective film is configured to reduce a loss of the laser beam transmitted to the rear facet. The refractive indices of the anti-reflective film and the highly-reflective film are greater than 2, and the thickness of the highly-reflective film is greater than the thickness of the anti-reflective film.

In certain embodiments, the anti-reflective film and the highly-reflective film include tantalum pentoxide.

In certain embodiments, the optical device further includes a capping layer disposed on a top facet of the semiconductor stack structure, wherein the refractive index of the capping layer is greater than 1.4.

In certain embodiments, the capping layer includes silicon dioxide or silicon nitride.

In certain embodiments, the semiconductor stack structure includes a substrate, an active layer, a first cladding layer, and a second cladding layer, wherein the active layer is disposed on the substrate, the first cladding layer is disposed between the substrate and the active layer, the second cladding layer is disposed on the active layer; the optical device further includes a first electrode layer and a second electrode layer, wherein the first electrode layer is disposed below substrate, the second electrode layer is disposed above second cladding layer, and at least a portion of the second electrode layer is exposed from the capping layer.

One aspect of the present disclosure provides another optical device, which includes a semiconductor stack structure, an anti-reflective film and a highly-reflective film; the semiconductor stack structure is configured to generate a laser beam when receiving a current, and emit the laser beam from a front facet of the semiconductor stack structure, wherein the front facet is a lateral side of the semiconductor stack structure; the anti-reflective film is disposed on the front facet of semiconductor stack structure, and is configured to increase the transmittance of the laser beam; the highly-reflective film is disposed on a rear facet of the semiconductor stack structure, and is configured to reduce a loss of the laser beam transmitted to the rear facet, wherein the rear facet is another lateral side of the semiconductor stack structure. The anti-reflective film and the highly-reflective film each includes a plurality of first dielectric films and at least one second dielectric film disposed alternately, wherein the plurality of first dielectric films and the second dielectric film have different refractive indices, and the refractive indices of the plurality of first dielectric films and the second dielectric film are greater than 1.4.

In some embodiments, one of the plurality of first dielectric films of the anti-reflective film is in contact with the front facet of the semiconductor stack structure, and one of the plurality of first dielectric films of the highly-reflective film is in contact with the rear facet of the semiconductor stack structure.

In some embodiments, the refractive index of the plurality of first dielectric films is greater than the refractive index of the second dielectric film, one of the plurality of first dielectric films of the anti-reflective film is disposed furthest away from the front facet of the semiconductor stack structure, and one of the plurality of first dielectric films of the highly-reflective film is disposed furthest away from the rear facet of the semiconductor stack structure.

In some embodiments, the plurality of first dielectrics film include tantalum pentoxide, and the second dielectric film includes silicon dioxide.

In some embodiments, the reflectivity of the anti-reflective film is lower than about 0.2%, and the reflectivity of the highly-reflective film is higher than about 80%.

In some embodiments, a first thickness of the anti-reflective film is less than a second thickness of the highly-reflective film, wherein the first thickness is at least 450 nm, and second thickness is about 1200 nm.

In some embodiments, the optical device further includes a capping layer, which is disposed on semiconductor stack structure and includes a plurality of third dielectric films and a plurality of fourth dielectric films disposed alternately, wherein the refractive index of the plurality of third dielectric films is different from the refractive index of the plurality of fourth dielectric films, and the refractive indices of the plurality of third dielectric films and the plurality of fourth dielectric films are greater than about 1.4.

In some embodiments, an amount of the plurality of third dielectric films equals to an amount of the plurality of fourth dielectric films.

In some embodiments, the plurality of third dielectric films include silicon dioxide, and the plurality of fourth dielectric films include silicon nitride.

In some embodiments, the plurality of third dielectric films include silicon nitride, and the plurality of fourth dielectric films include silicon dioxide.

In some embodiments, the semiconductor stack structure includes a substrate, an active layer, a first cladding layer, a second cladding layer, wherein the active layer is disposed on the substrate, the first cladding layer is disposed between the substrate and the active layer, and the second cladding layer is disposed on the active layer; the optical device further includes a first electrode layer and a second electrode layer, wherein the first electrode layer is disposed below substrate, the second electrode layer is disposed above second cladding layer, and at least a portion of the second electrode is exposed from the capping layer.

Another aspect of the present disclosure provides a method for fabricating an optical device, including: providing a semiconductor stack structure, which can generate a laser beam when receiving a current, and the laser beam is emitted from a front facet of the semiconductor stack structure, wherein the front facet is a lateral side of the semiconductor stack structure; and coating a first dielectric film on the front facet and a rear facet of the semiconductor stack structure, wherein the refractive index of the first dielectric film is greater than about 2, and the rear facet is another lateral side of the semiconductor stack structure.

In some embodiments, the method for fabricating the optical device further includes: coating a second dielectric film on a surface of the first dielectric film, wherein the refractive index of the second dielectric film is approximately greater than about 1.4; and coating another first dielectric film on a surface of the second dielectric film.

In some embodiments, the method for fabricating the optical device further includes: coating a third dielectric film on a top facet of the semiconductor stack structure, wherein the refractive index of the third dielectric film is greater than about 1.4.

In some embodiments, the method for fabricating the optical device further includes: coating a fourth dielectric film on the third dielectric film, wherein the refractive index of the fourth dielectric film is different from the refractive index of the third dielectric film, and the refractive index of the fourth dielectric film is greater than about 1.4.

The optical device provided by the present disclosure uses a film with a refractive index of no less than about 1.4 as an anti-reflective film, a highly-reflective film, and a capping layer, which cover the front facet, rear facet, and top facet of a semiconductor stack structure, so as to block moisture from entering the semiconductor stack structure; therefore, the optical device provided by the present disclosure can be applied to optical communication systems that are usually assembled in a high humidity environment, without the need to add an additional metal or ceramic package housing, thereby realizing the advantages of lower costs and reducing assembly steps.

### BRIEF DESCRIPTION OF THE DRAWINGS

Aspects of the present disclosure are best understood from the following detailed description when read with the accompanying drawings, and like reference numerals across the embodiments refer to like elements.

FIG. 1 is a cross-sectional view illustrating a conventional package housing of a semiconductor laser.

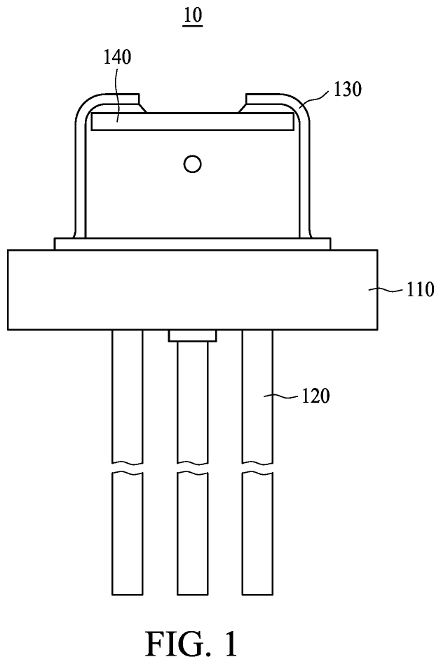

FIG. 2 is an elevation view illustrating a conventional package housing of a semiconductor laser.

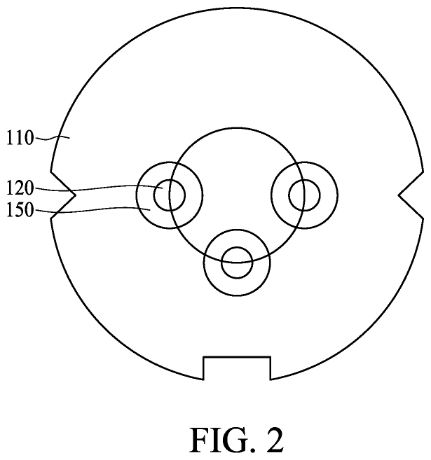

FIG. 3 is a perspective view illustrating an optical device, in accordance with some embodiments of the present disclosure.

FIG. 4 is a side view illustrating an optical device, in accordance with some embodiments of the present disclosure.

FIG. 5 is a cross-sectional view illustrating a semiconductor stack structure, in accordance with some embodiments of the present disclosure.

FIG. 6 is a perspective view illustrating an optical device, in accordance with some embodiments of the present disclosure.

FIG. 7 is a side view illustrating an optical device, in accordance with some embodiments of the present disclosure.

FIG. 8 is a cross-sectional view illustrating a semiconductor stack structure, in accordance with some embodiments of the present disclosure.

FIG. 9 is a cross-sectional view illustrating an anti-reflective film, in accordance with some embodiments of the present disclosure.

FIG. 10 is a cross-sectional view illustrating an anti-reflective film, in accordance with some embodiments of the present disclosure.

FIG. 11 is a cross-sectional view illustrating a capping layer, in accordance with some embodiments of the present disclosure.

FIG. 12 is a flowchart illustrating a method for fabricating an optical device, in accordance with some embodiments of the present disclosure.

FIG. 13A to FIG. 13D are schematic diagrams of intermediate stages of the method of fabricating an optical device, in accordance with some embodiments of the present disclosure.

### DETAILED DESCRIPTION

Various embodiments or examples according to the present disclosure as illustrated in the drawings are described below in more specific terms. It should be understood that these descriptions are illustrative only and are not intended to limit the present disclosure. Any changes or modifications to the embodiments described, and any further application of the principles described herein, are common practice to those having ordinary skill in the art to which this disclosure relates. The present disclosure may repeat reference numerals and/or letters in various embodiments; however, this does not mean that one or more features of one embodiment will necessarily be present in another embodiment, even if the same reference numeral is used.

Spatially relative terms, such as “beneath,” “below,” “lower,” “above,” “on,” “upper” and the like, may be used herein for ease of description to describe one element or feature's relationship to another element(s) or feature(s) as illustrated in the drawings. These spatially relative terms are intended to encompass different orientations of the device in use or operation in addition to the orientation depicted in the drawings. The device may be otherwise oriented (rotated 90 degrees or at other orientations) and the spatially relative descriptors used herein may likewise be interpreted accordingly.

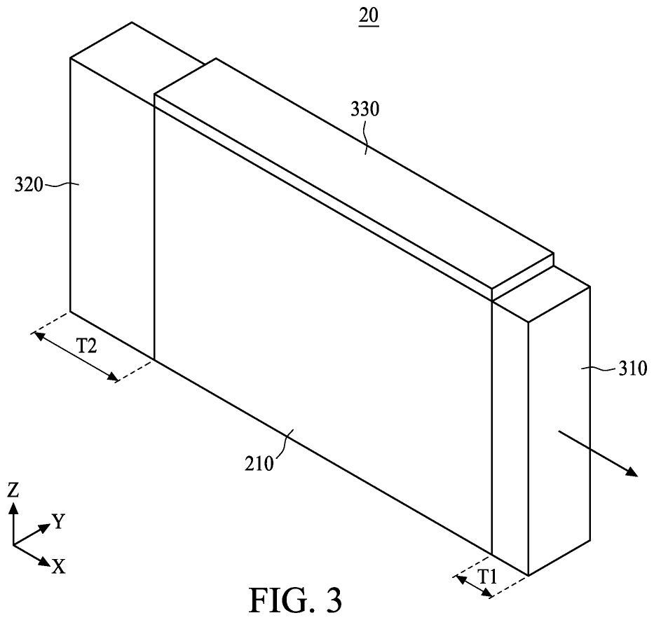

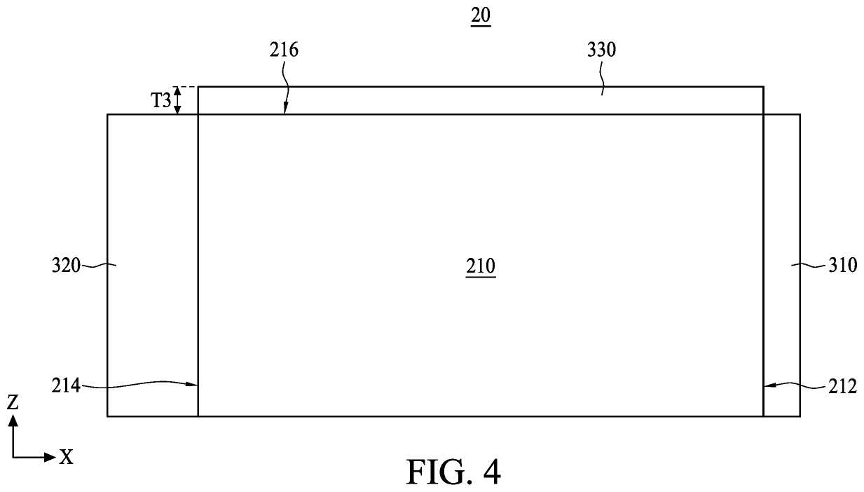

Reference is made to FIG. 3 and FIG. 4; FIG. 3 is a perspective view illustrating an optical device 20, in accordance with some embodiments of the present disclosure, and FIG. 4 is a side view illustrating the optical device 20, in accordance with some embodiments of the present disclosure. The optical device 20 includes a semiconductor stack structure 210, an anti-reflective film 310 disposed at a front facet 212 of the semiconductor stack structure 210, a highly-reflective film 320 disposed at a rear facet 214 of the semiconductor stack structure 210, and a capping layer 330 disposed at the top facet 216 of the semiconductor stack structure 210, wherein the front facet 212 and the rear facet 214 are two opposite and substantially parallel lateral sides of the semiconductor stack structure 210, and the top facet 216 adjoins the front facet 212 and the rear facet 214.

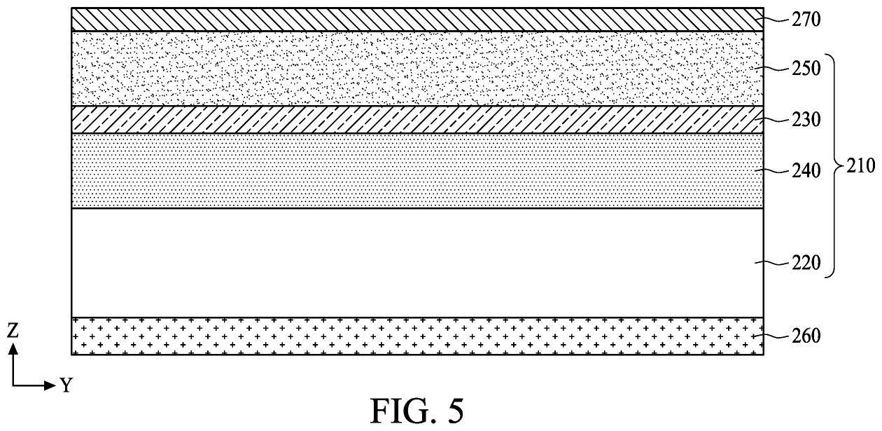

The semiconductor stack structure 210 includes a plurality of semiconductor layers (as shown in FIG. 5), and these semiconductor layers are configured as an edge emitting laser diode, meaning that when the semiconductor stack structure 210 is under a bias, it generates a laser beam emitted from the front facet 212 thereof. Reference is made to FIG. 5, wherein the semiconductor stack structure 210 includes a substrate 220, an active layer 230, a first cladding layer 240 and a second cladding layer 250; the first cladding layer 240, the active layer 230 and the second cladding layer 250 are sequentially disposed on the substrate 220 from bottom to top. The optical device 20 may further include a first electrode layer 260 and a second electrode layer 270, to facilitate application of bias to the semiconductor stack structure 210; the first electrode layer 260 is disposed on a lower surface of the substrate 220 or therebelow, and the second electrode layer 270 is disposed on an upper surface of the second cladding layer 250 or thereabove.

The substrate 220 is a growth and/or load-bearing base, and the substrate 220 may include indium phosphide (InP). The active layer 230 may include a multiple-quantum well structure to enhance the light emitting efficiency of the optical device 20; in some embodiments, a double heterostructure or a single quantum well structure may also serve as the active layer 230. When an appropriate voltage is applied to the two ends of the semiconductor stack structure 210 (i.e., the first electrode layer 260 and the second electrode layer 270), carriers (including electrons and holes) are injected into the active layer 230 and complexed in the active layer 230 to emit light.

The first cladding layer 240 has a refractive index that is lower than the active layer 230, to increase the likelihood of total internal reflection of light emitted from the active layer 230 at the interface between the active layer 230 and the first cladding layer 240. Similarly, the second cladding layer 250 also has a refractive index that is lower than the active layer 230 to increase likelihood of total internal reflection of light at the interface between the active layer 230 and the second cladding layer 250. In other words, the first cladding layer 240 and the second cladding layer 250 serve to allow most of the light emitted from the active layer 230 to be confined in the active layer 230 and transmitted in a total internal reflection manner between the anti-reflective film 310 and the highly-reflective film 320, and ultimately emitted from the anti-reflective film 310.

In some embodiments, the first cladding layer 240 and the second cladding layer 250 may include indium phosphide, and may be doped to have different conductivity types so as not to affect the carrier injection efficiency of the semiconductor stack structure 210 when subjected to a bias voltage. For example, when the first cladding layer 240 is an n-type semiconductor layer, the second cladding layer 250 is a p-type semiconductor layer.

Referring back to FIG. 3 and FIG. 4, the reflectivity of the anti-reflective film 310 may be lower than about 0.2% to increase the efficiency of light emission. Specifically, the anti-reflective film 310 may reduce the reflection of the light at the front facet 212 of the semiconductor stack structure 210, so that the light can be emitted from the front facet 212. The reflectivity of the highly-reflective module 320 may be higher than about 80% to prevent the light from being emitted from the rear facet 214 of the semiconductor stack structure 210 and reduce the loss of light at the rear facet 214 of the semiconductor stack structure 210.

In FIG. 3and FIG. 4, the anti-reflective film 310 includes single-layered structure, and the highly-reflective film 320 includes single-layered structure. Further, the anti-reflective film 310 and the highly-reflective film 320 may be films having a high refractive index; herein, the high refractive index film layer refers to a film layer having a refractive index of at least 1.4. Generally speaking, a film layer with a high refractive index has a denser structure and thus has a better moisture blocking ability and can serve as a moisture blocking layer. Therefore, the selection of the anti-reflective film 310 with a high refractive index prevents moisture from entering the semiconductor stacking structure 210 from the front facet 212 of the semiconductor stacking structure 210, and the selection of the highly-reflective film 320 with a high refractive index prevents moisture from entering the semiconductor stacking structure 210 from the rear facet 214 of the semiconductor stacking structure 210.

In some embodiments, the anti-reflective film 310 may be formed on the front facet 212 of the semiconductor stack structure 210 by vapor deposition using a dielectric material having a refractive index greater than about 2. The highly-reflective film 320 may be formed on the rear facet 214 of the semiconductor stack structure 210 by vapor deposition using a dielectric material having a refractive index greater than about2.

The anti-reflective film 310 and the highly-reflective film 320 may be made using the same material but have different reflectivity by having different thicknesses. The anti-reflective film 310 and the highly-reflective film 320 may be made using tantalum pentoxide (Ta2O5), with the anti-reflective film 310 having a first thickness T1 and the highly-reflective film 320 having a second thickness T2. The first thickness T1 is less than the second thickness T2 to provide a lower reflectivity to allow light to be emitted from the front facet 212 of the semiconductor stack structure 210. In some embodiments, the first thickness T1 of the anti-reflective film 310 is no less than about 450 nm and may be, for example, about 700 nm; and the second thickness T2 of the highly-reflective film 320 may be about 1200 nm.

The capping layer 330 is made of a dielectric material having a high refractive index to provide better waterproofing performance. Specifically, the capping layer 330 is made of a material having a refractive index of at least 1.4 and different from the anti-reflective film 310 and the highly-reflective film 320. In certain embodiments, the capping layer 330 may be made of silicon dioxide (SiO2) or silicon nitride (Si3N4), and the capping layer 330 may have a third thickness T3. The third thickness T3 is less than the first thickness T1, and the third thickness T3 is less than the second thickness T2. The capping layer 330 may be formed, for example, by vapor deposition on the top facet 216 of the semiconductor stack structure 210 and the second electrode layer 270. In some embodiments, at least a portion of the second electrode layer 270 is exposed from the capping layer 330 to facilitate application of voltage to the semiconductor stack structure 210. In some embodiments, the second electrode layer 270 is brought into contact with the second cladding layer 250, for example, by a damascene process after deposition of the capping layer 330. In alternative embodiments, the first electrode layer 260 and the second electrode layer 270 is formed on the semiconductor stack structure 210 prior to deposition of the anti-reflective film 310, the highly-reflective film 320, and the capping layer 330, and when depositing the capping layer 330, at least a portion the second electrode layer 270 is shielded with a blocker so that at least a portion of the second electrode layer 270 is exposed from the capping layer 330. Forming the first and second electrode layers 260 and 270 prior to the deposition of the anti-reflective film 310, the highly-reflective film 320, and the capping layer 220 may have a better moisture blocking capability than forming the first and second electrode layers using the damascene process.

In summary, the optical device 20 provided by the present disclosure deposits a film layer with high refractive index and good waterproof performance on the front facet 212, the rear facet 214, and the top facet 216 of the semiconductor stack structure 210, respectively, to provide protection to prevent moisture from entering the semiconductor stack structure 210. Therefore, the optical device 20 provided by the present disclosure can be used in the optical communication system which is usually assembled in a high humidity environment with the advantage of lowering the cost and reducing the number of assembly steps.

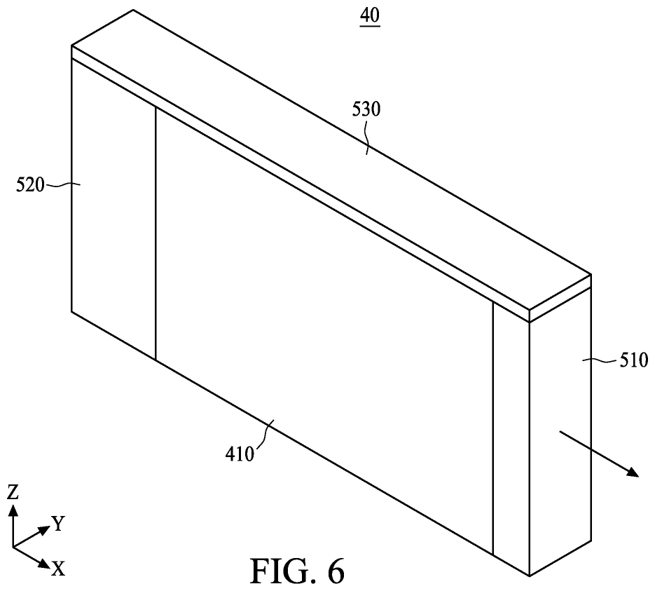

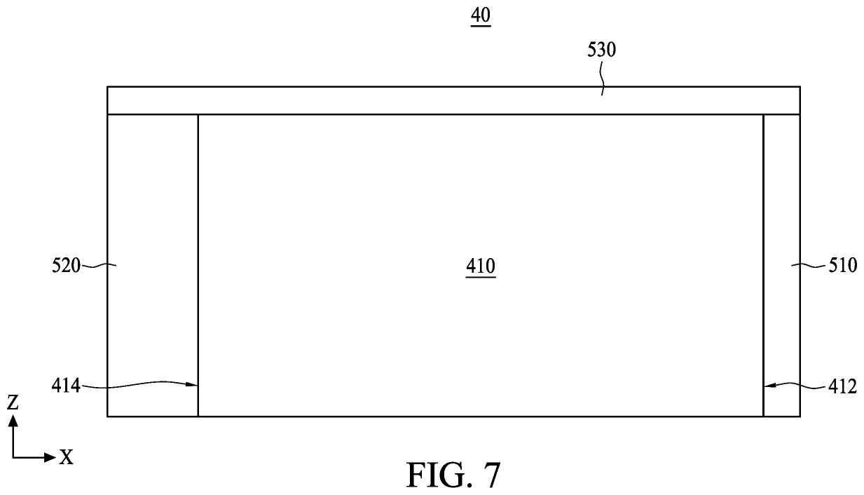

Reference is made to FIG. 6 and FIG. 7; FIG. 6 is a perspective view illustrating an optical device 40, in accordance with some embodiments of the present disclosure, and FIG. 7 is a side view illustrating the optical device 40, in accordance with some embodiments of the present disclosure. The optical device 40 includes a semiconductor stack structure 410, an anti-reflective film 510 disposed at a front facet 412 of the semiconductor stack structure 410, and a highly-reflective film 520 disposed at a rear facet 414 of the semiconductor stack structure 410; wherein, the front facet 412 and the rear facet 414 are two opposite and substantially parallel lateral sides of the semiconductor stack structure 410.

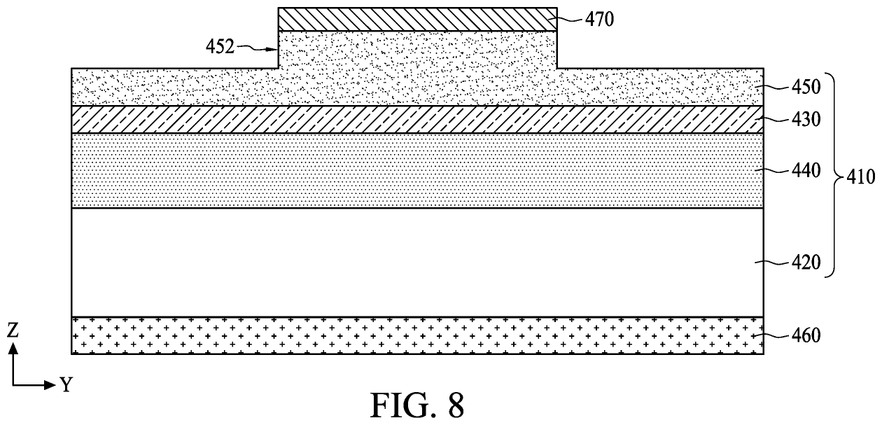

The semiconductor stack structure 410 includes a plurality of semiconductor layers (as shown in FIG. 8), and these semiconductor layers are configured as an edge emitting laser diode, meaning that when the semiconductor stack structure 410 is under a bias, it generates a laser beam emitted from the front facet 412 thereof. Reference is made to FIG. 8, wherein the semiconductor stack structure 410 includes a substrate 420, an active layer 430, a first cladding layer 440 and a second cladding layer 450. The active layer 430 is disposed between the first cladding layer 440 and the second cladding layer 450, and the first cladding layer 440 is in contact with the substrate 420; a portion of the upper part of the second cladding layer 450 is removed to form a ridge masa 452. The optical device 40 further includes a first electrode layer 460 and a second electrode layer 470; the first electrode layer 460 is disposed on a lower face of the substrate 420, and the second electrode layer 470 may be disposed on the ridge masa 452 and is in contact with the second cladding layer 450.

The ridge masa 452 may limit the size and position of the current passing through the active layer 430 when a forward bias is applied to the semiconductor stack structure 410, so that the carriers injected into the active layer 430 are complexed only in a localized region under the ridge masa 452. Therefore, compared with the semiconductor stack structure 210 shown in FIG. 5, the semiconductor stack structure 410 shown in FIG. 8 has an even smaller light emitting area to maintain the stability of the optical mode.

The first cladding layer 440 and the second cladding layer 450 may have a lower refractive index than the active layer 430 to allow most of the light emitted from the active layer 430 to be transmitted in a total internal reflection manner between the anti-reflective film 310 and the highly-reflective film 320. The first cladding layer 440 and the second cladding layer 450 may be composed of a semiconductor material with a higher energy gap in order to create a barrier of carriers to prevent the electrons or the electric holes from escaping from the active layer 430 to reduce the quantum efficiency.

Referring back to FIG. 6 and FIG. 7, the reflectivity of the anti-reflective film 510 is different from the reflectivity of the highly-reflective film 520; further, the reflectivity of the anti-reflective film 510 is less than the reflectivity of the highly-reflective film 520. Therefore, when applying an appropriate voltage at the first electrode layer 460 and the second electrode layer 470 of the semiconductor stack structure 410 to excite the active layer 430, the laser beam may oscillate back and forth between the anti-reflective film 510 and the highly-reflective film 520, and ultimately emit from the anti-reflective film 510. In some embodiments, the reflectivity of the anti-reflective film 510 is less than about 0.2%, and the reflectivity of the highly-reflective module 520 is greater than about 80%.

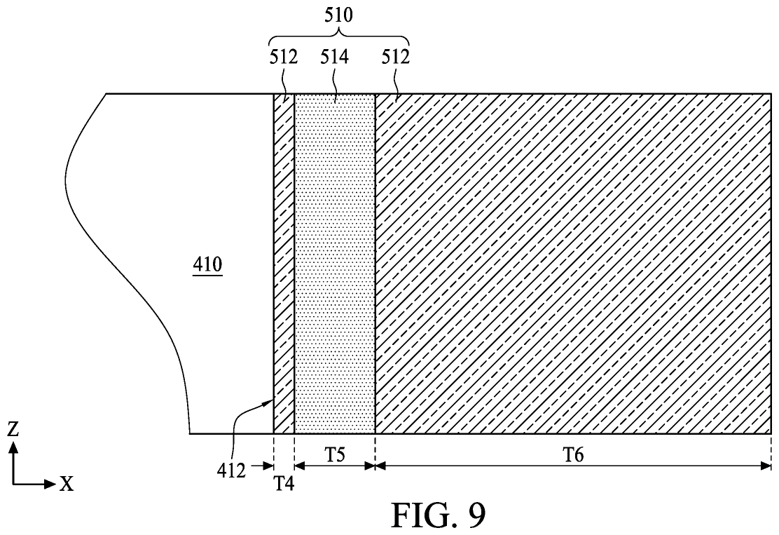

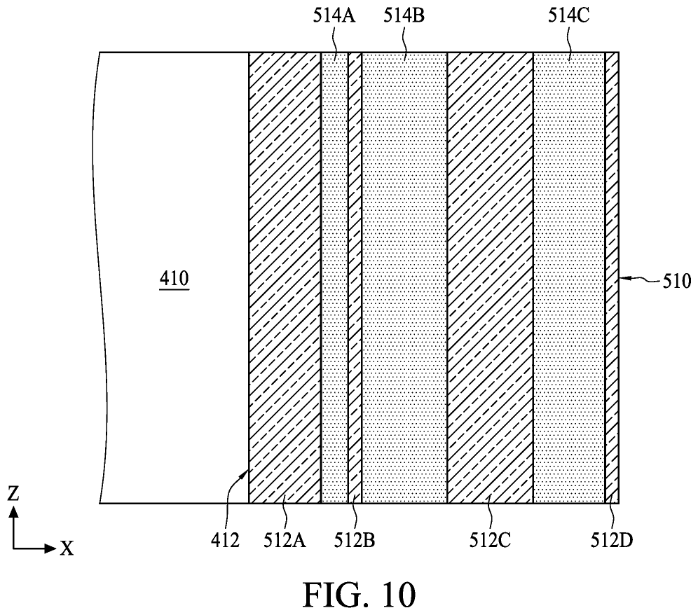

The anti-reflective film 510 may include a multi-layered structure, and the highly-reflective film 520 may include a multi-layered structure. Specifically, the anti-reflective film 510 and the highly-reflective film 520 are layers that include alternating configurations of a higher refractive index material and a lower refractive index material. As used herein, “higher” and “lower” are used to indicate relative refractive indices, i.e., the refractive indices of one of the materials in the anti-reflective film 510/highly-reflective film 520 are higher than the refractive indices of the other material in the anti-reflective film 510/highly-reflective film 520. For example, the anti-reflective film 510 may include a first dielectric film 512 and a second dielectric film 514 in alternating configurations, as shown in FIG. 9 and FIG. 10. The first dielectric film 512 has a first refractive index, and the second dielectric film 514 has a second refractive index that is smaller than the first refractive index. The first refractive index of the first dielectric film 512 and the second refractive index of the second dielectric film 514 are at least 1.4. In some embodiments, the first refractive index may be greater than about 2, and the second refractive index may be about 1.5. For example, the first dielectric film layer 512 may be formed of tantalum pentoxide, and the second dielectric film layer 514 may be formed of silicon dioxide. Since the film layer formed of the higher refractive index material has a denser structure than the film layer formed of the lower refractive index material, it can be used as a moisture barrier layer to block moisture from entering the semiconductor stack structure; therefore, typically, the outermost layer of the anti-reflective film layer 510 (i.e., the layer furthest away from the front facet 410 of the semiconductor stack structure 410) is the first dielectric film layer 512 that contains the higher refractive index material.

The second dielectric film 514 may include any number of layers, and the number of first dielectric films 512 is one more than the number of second dielectric films 514; the film layer that typically contacts the front facet 412 of the semiconductor stack structure 410 is the first dielectric film 512 having a higher refractive index.

Reference is made to FIG. 9; as an example, the anti-reflective film 510 in FIG. 9 is a three-layered structure, which includes two first dielectric films 512 and a second dielectric film 514; the second dielectric film layer 514 is configured between the first dielectric films 512. Each of the first dielectric films 512 and the second dielectric film 514 in the anti-reflective film layer 510 may have a different thickness to enhance the moisture blocking ability. The first dielectric film 512 in contact with the semiconductor stack structure 410 has a first thickness T4, the second dielectric film layer 514 has a second thickness T5, and the first dielectric film layer 512 furthest from the semiconductor stack structure 410 has a third thickness T6. The first thickness T4 is less than the second thickness T5, and the third thickness T6 is greater than the second thickness T5. In some embodiments, the first thickness T4 is about 20 nm, the second thickness T5 is about 80 nm, and the third thickness T6 is about 389 nm.

Reference is made to FIG. 10; as an example, the anti-reflective film layer 510 shown in FIG. 10 is a seven-layered structure, wherein the seven-layered structure includes four first dielectric films 512A, 512B, 512C, and 512D arranged in left-to-right order, and three second dielectric films 514A, 514B, and 514C arranged in left-to-right order, with the first dielectric film layer 512A in contact with the front facet 412 of the semiconductor stack structure 410, the second dielectric films 514A, 514B, and 514C disposed between two neighboring first dielectric films 512A, 512B, 5142, and 512D. The first dielectric films 512A, 512B, 512C, and 512D have a first refractive index and the second dielectric films 514A, 514B, and 514C have a second refractive index, wherein the first and second refractive indices are respectively at least 1.4. In some embodiments, the first dielectric films 512A, 512B, 512C, and 512D may be made of tantalum pentoxide having a first refractive index that may be greater than about 2, and the second dielectric films 514A, 514B and 514C may be made of silicon dioxide having a second refractive index of about 1.5.

The number of layers of the anti-reflective film 510 and the thickness of each of the layers in the anti-reflective film 510 may be adjusted according to the wavelength band of the laser beam emitted from the semiconductor stack structure 410 in order to improve the transmittance of the laser beam. Table 1 below shows the thickness data of the first dielectric films 512A, 512B, 512C, and 512D and the second dielectric films 514A, 514B, and 514C in the anti-reflective film 510 shown in FIG. 10, wherein the thicknesses are expressed in units of nanometers.

TABLE 1

| | Film | | | | | | |
|---|---|---|---|---|---|---|---|
| | 512A | 514A | 512B | 514B | 512C | 514C | 512D |
| Thickness | 139.5 | 51.6 | 29 | 164 | 177 | 150 | 29.4 |

Referring back to FIG. 6 and FIG. 7, in which the highly-reflective film 520 may be a single-layered or a multi-layered structure. When the highly-reflective film 520 is a single-layered structure, tantalum pentoxide having a refractive index greater than about 2 may be selected to be formed on the rear facet 414 of the semiconductor stack structure 410 by vapor deposition. When the highly-reflective film 520 is a multi-layered structure, it may be composed of a tantalum pentoxide film layer having a refractive index greater than about 2 and a silicon dioxide film layer having a refractive index of about 1.5 disposed alternately, and the outermost layer (i.e. the layer furthest away from the rear facet 414 of the semiconductor stack structure 410) includes a higher refractive index material. The silicon dioxide film may include any number of layers, with the number of tantalum pentoxide films being one more layer than the number of silicon dioxide films; typically the layer that contacts the rear facet 414 of the semiconductor stack structure 410 is a tantalum pentoxide film layer.

The optical device 40 may further include a capping layer 530 disposed above the semiconductor stack structure 410, the anti-reflective film 510, and the highly-reflective film 520. In some embodiments, a protective layer (not shown) may be disposed on both sides of the ridged masa 452 prior to the formation of the capping layer 530, and the protective layer has an upper surface that is substantially co-planar with the top surface of the ridged platform 452 and/or the top surface of the second electrode layer 470 to allow the capping layer 530 to be subsequently deposited on the protective layer and the second electrode layer 470 with a flat profile. In some embodiments, the capping layer 530 have a profile that follows the profile of the ridged masa 452 and/or the second electrode layer 470.

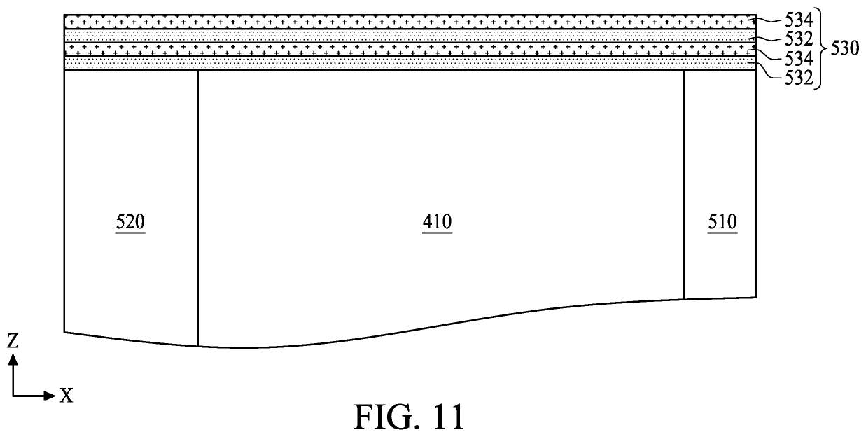

The capping layer 530 is a layer that includes a higher refractive index material and/or a lower refractive index material; wherein “higher” and “lower” are used to indicate relative refractive indices, i.e., the refractive index of one material is higher than the refractive index of the other material in the capping layer 530. For example, the capping layer 530 may include third dielectric films 532 and fourth dielectric films 534 that are disposed alternately, as shown in FIG. 11. Compared with the single-layer capping layer 330 composed of silicon dioxide or silicon nitride in FIG. 4, the multi-layer capping layer 530 shown in FIG. 11 is composed with third dielectric films 532 and fourth dielectric film layers 534 disposed alternately and has better moisture barrier capabilities.

The third dielectric film 532 may include any number of layers, the fourth dielectric film 534 has the same number of layers as the third dielectric film 532, and the thickness of the third dielectric film 532 is substantially the same as the thickness of the fourth dielectric film 534. The capping layer 530 in FIG. 11 as an example of a four-layer dielectric film, which includes two third dielectric films 532 and two fourth dielectric films 534; and one of the third dielectric films 532 contacts the semiconductor stack structure 410, the anti-reflective film 510, and the highly-reflective film 520.

In some embodiments, the third dielectric film 532 has a third refractive index, and the fourth dielectric film 534 has a fourth refractive index that is greater than the third refractive index; wherein the third refractive index and the fourth refractive index are both at least 1.4. For example, the third dielectric film 532 may be made of silicon dioxide having a refractive index of about 1.5, and the fourth dielectric film 534 may be made of silicon nitride having a refractive index of greater than about 2. In other embodiments, the third refractive index of the third dielectric film 532 may be greater than the fourth refractive index of the fourth dielectric film 534; for example, the third dielectric film 532 may be made of silicon nitride having a refractive index greater than about 2, and the fourth dielectric film 534 may be made of silicon dioxide having a refractive index greater than about 1.5.

In view of the above, the optical device 40 provided by the present disclosure not only deposits an anti-reflective film 510 and a highly-reflective film 520 having a high refractive index and good waterproofing performance on the front facet 412 and the rear facet 414 of the semiconductor stack structure 410, respectively, but also deposits a capping layer 530 on top of the semiconductor stack structure 410, the anti-reflective film 510, and the highly-reflective film 520 to provide protection to prevent moisture from entering the semiconductor stack structure 410. Therefore, the optical device 40 disclosed herein can be in the optical communication system which is usually assembled in a high humidity environment without the need to add an additional metal or ceramic package housing, thereby achieving the advantage of lowering the cost and reducing the number of assembly steps.

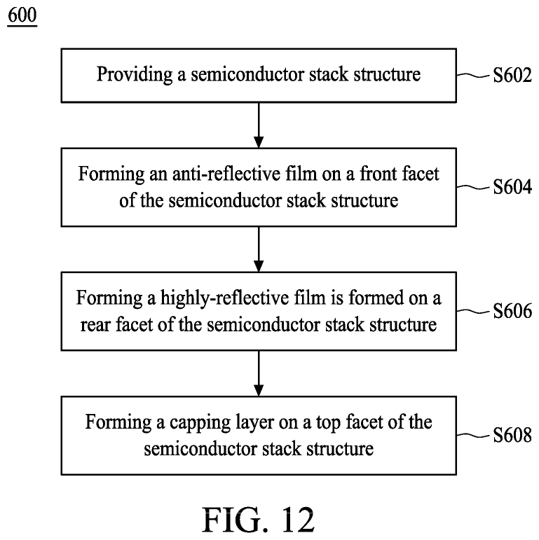

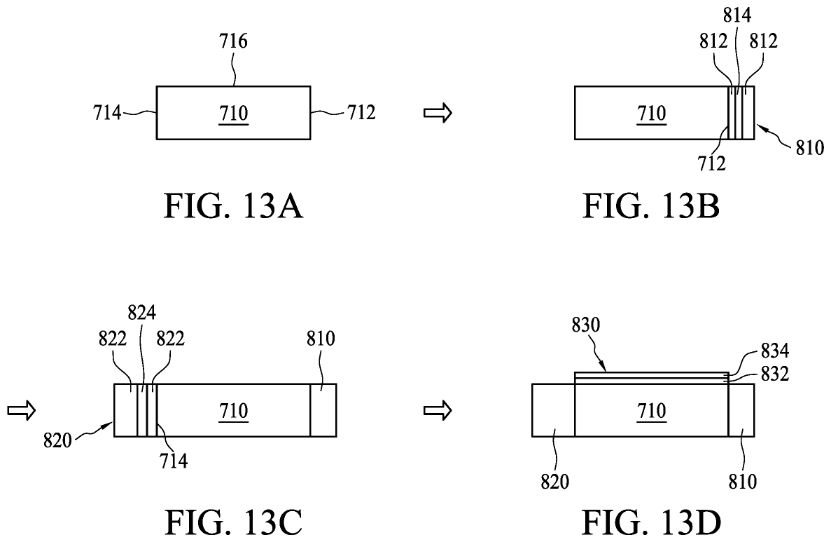

FIG. 12 is a flowchart illustrating a method for fabricating an optical device according to certain embodiments of the present disclosure. Reference is made to FIG. 12, in which the method 600 for fabricating an optical device includes step S602, step S604, step S606 and step S608, and FIG. 13A to FIG. 13D are schematic diagrams of intermediate stages of the method of for fabricating the optical device, in accordance with some embodiments of the present disclosure.

Referring to FIG. 13A, in step S602 of FIG. 12, a semiconductor stack structure 710 is provided; this semiconductor stack structure 710 can generate a laser beam when receiving a current, and the laser beam generated by the semiconductor stack structure 710 is emitted from a front facet 712 thereof; wherein, the front facet 712 is a lateral side of the semiconductor stack structure 710.

Referring to FIG. 13B, in step S604 of FIG. 12, an anti-reflective film 810 is formed on the front facet 712 of the semiconductor stack structure 710, wherein the anti-reflective film 810 may be formed on the front facet 712 of the semiconductor stack structure 710 by one or more chemical vapor deposition (CVD) or physical vapor deposition (PVD) processes. The anti-reflective film 810 may be a single dielectric film layer and include a material with a refractive index greater than about 2, such as tantalum pentoxide. The anti-reflective film 810 may be a multi-layered structure; for example, the anti-reflective film 810 includes a plurality of first dielectric films 812 and at least one second dielectric film 814, which stack on top of each other alternately.

The first dielectric film 812 and the second dielectric film 814 have different refractive indices; the refractive indices of the first dielectric film 812 and the second dielectric film 814 are at least 1.4. The refractive index of the first dielectric film 812 that is in contact with the front facet 712 of the semiconductor stack structure 710 is greater than the refractive index of the second dielectric film 814. The second dielectric film 814 may include any number of layers, and the number of first dielectric films 812 is one more than the number of second dielectric films 814; in other words, the anti-reflective film 810 is an odd-number layer structure. In some embodiments, the first dielectric film 812 includes tantalum pentoxide having a refractive index greater than about 2, and the second dielectric film 814 includes silicon dioxide having a refractive index is about 1.5.

Referring to FIG. 13C, in step S606 of FIG. 12, a highly-reflective film 820 is formed on a rear facet 714 of the semiconductor stack structure 710. The rear facet 714 is a lateral side of the semiconductor stack structure 710 and substantially parallel to the front facet 712. The highly-reflective film 820 may be formed on the rear facet 714 of the semiconductor stack structure 710 by one or more of CVD or PVD processes. The highly-reflective film 820 may be a single-layered structure or a multi-layered structure including third dielectric films 822 and fourth dielectric films 824 with different refractive indices that are stacked alternately. The highly-reflective film 820 with a single-layered structure may include a material having a refractive index greater than about 2, such as tantalum pentoxide. The third dielectric film 822 and the fourth dielectric film 824 in the highly-reflective film 820 of the multi-layered structure may be tantalum pentoxide with a refractive index of greater than about 2 and silicon dioxide with a refractive index of about 1.5, respectively. In other words, the highly-reflective film 820 may have the same material and dielectric film layer arrangement order as the anti-reflective film 810, with the difference that the highly-reflective film 820 has a thicker thickness than the anti-reflective film layer 810 to prevent the laser beam from passing through the highly-reflective film 820.

Referring to FIG. 13D, in step S608 of FIG. 12, a capping layer 830 is formed on a top facet 716 of the semiconductor stack structure 710. The top facet 716 adjoins the front facet 712 and the rear facet 714. The capping layer 820 may be formed on the top facet 716 of the semiconductor stack structure 710 by one or more CVD or PVD processes. In some embodiments, if the capping layer 830 is formed after the anti-reflective film 810 and the highly-reflective film 820, then the capping layer 830 may simultaneously cover the top facet 716, the anti-reflective film 810 and the highly-reflective film 820 of the semiconductor stack structure 710, to increase its moisture prevention capability.

In some embodiments, the capping layer 830 may be a single-layered structure, and includes a material with a refractive index greater than about 1.4, such as silicon dioxide or silicon nitride. In some embodiments, the capping layer 830 includes fifth dielectric films 832 and sixth dielectric films 834 that stack on top of each other alternately, and the capping layer 830 is an even-number layer structure. The fifth dielectric film 832 and the sixth dielectric film 834 have different refractive indices, and both have a refractive index of at least 1.4. In some embodiments, the capping layer 830 is a multi-layered structure with silicon dioxide and silicon oxide disposed alternately.

Although the disclosure and its advantages have been described in detail, it should be understood that various modifications, substitutions and replacements can be made without departing from the spirit and scope of the present disclosure as defined by the appended claims. For example, many of the processes discussed above may be implemented with different methodologies, and may be replaced by other processes, or combinations thereof.

In addition, the scope of the present application is not limited to specific examples of processes, machines, manufactures, devices, methods and steps described in the specification. Those skilled in the art can understand from the disclosure of the present application that existing or future developed processes, machines, manufactures, devices, methods and steps that have the same functions or achieve substantially the same results as the corresponding embodiments described herein can be used according to this disclosure. Accordingly, such process, machine, manufacture, composition of matter, means, method, or step fall within the protection scope of the present application.

What is claimed is:

1. An optical device, comprising:
a semiconductor stack structure, configured to generate a laser beam when receiving a current, and emit the laser beam from a front facet of the semiconductor stack structure, wherein the front facet is a lateral side of the semiconductor stack structure;
an anti-reflective film, disposed on the front facet, and configured to increase of the transmittance of the laser beam; and
a highly-reflective film, disposed on a rear facet of the semiconductor stack structure, wherein the rear facet is another lateral side of the semiconductor stack structure, and the highly-reflective film is configured to reduce a loss of the laser beam transmitted to the rear facet,
wherein, the anti-reflective film and the highly-reflective film each has a refractive index greater than about 2, and a thickness of the highly-reflective film is greater than a thickness of the anti-reflective film.

2. The optical device according to claim 1, wherein the anti-reflective film and the highly-reflective film comprise tantalum pentoxide (Ta₂O₅).

3. The optical device according to claim 1, further comprising:
a capping layer, disposed on a top facet of the semiconductor stack structure, wherein a refractive index of the capping layer is greater than about 1.4.

4. The optical device according to claim 3, wherein the capping layer comprise silicon dioxide (SiO₂) or silicon nitride (Si₃N₄).

5. The optical device according to claim 3, wherein:
the semiconductor stack structure comprises:
a substrate;
an active layer, disposed on the substrate;
a first cladding layer, disposed between the substrate and the active layer; and
a second cladding layer, disposed on the active layer; and
the optical device further comprises:
a first electrode layer, disposed above the substrate; and
a second electrode layer, disposed above the second cladding layer, and at least a portion of the second electrode layer is exposed from of the capping layer.

6. An optical device, comprising:
a semiconductor stack structure, configured to generate a laser beam when receiving a current, and emit the laser beam from a front facet of the semiconductor stack structure, wherein the front facet is a lateral side of the semiconductor stack structure;
an anti-reflective film, disposed on the front facet, and configured to increase of the transmittance of the laser beam; and
a highly-reflective film, disposed on a rear facet of the semiconductor stack structure, wherein the rear facet is another lateral side of the semiconductor stack structure, and the highly-reflective film is configured to reduce a loss of the laser beam transmitted to the rear facet,
wherein, the anti-reflective film and the highly-reflective film each comprises a plurality of first dielectric films and at least one second dielectric film disposed alternately, wherein the plurality of first dielectric films and the second dielectric film have different refractive indices, and the refractive indices of the plurality of first dielectric films and the second dielectric film are greater than about 1.4.

7. The optical device according to claim 6, wherein one of the plurality of first dielectric films of the anti-reflective film is in contact with the front facet, and one of the plurality of first dielectric films of the highly-reflective film is in contact with the rear facet.

8. The optical device according to claim 6, wherein a refractive index of the plurality of first dielectric films is greater than a refractive index of the second dielectric film, one of the plurality of first dielectric films of the anti-reflective film is disposed furthest away from the front facet, and one of the plurality of first dielectric films of the highly-reflective film is disposed furthest away from the rear facet.

9. The optical device according to claim 8, wherein the plurality of first dielectric films comprise tantalum pentoxide (Ta₂O₅), and the second dielectric film comprises silicon dioxide (SiO₂).

10. The optical device according to claim 6, wherein a reflectivity of the anti-reflective film is lower than about 0.2%, and a reflectivity of the highly-reflective film is higher than about 80%.

11. The optical device according to claim 6, wherein a first thickness of the anti-reflective film is less than a second thickness of the highly-reflective film, wherein the first thickness is at least 450 nm, and the second thickness is about 1200 nm.

12. The optical device according to claim 6, further comprising:
a capping layer, disposed on the semiconductor stack structure, wherein the capping layer comprises a plurality of third dielectric films and a plurality of fourth dielectric films disposed alternately, a refractive index of the plurality of third dielectric films is different from a refractive index of the plurality of fourth dielectric films, and the refractive indices of the plurality of third dielectric films and the plurality of fourth dielectric films are greater than about 1.4.

13. The optical device according to claim 12, wherein an amount of the plurality of third dielectric films equals to an amount of the plurality of fourth dielectric films.

14. The optical device according to claim 12, wherein the plurality of third dielectric films comprise silicon dioxide (SiO₂), and the plurality of fourth dielectric films comprise silicon nitride (Si₃N₄).

15. The optical device according to claim 12, wherein the plurality of third dielectric films comprise silicon nitride (Si₃N₄), and the plurality of fourth dielectric films comprise silicon dioxide (SiO₂).

16. The optical device according to claim 12, wherein:
the semiconductor stack structure comprises:
a substrate;
an active layer, disposed on the substrate;
a first cladding layer, disposed between the substrate and the active layer; and
a second cladding layer, disposed on the active layer; and
the optical device further comprises:
a first electrode layer, disposed below the substrate; and
a second electrode layer, disposed above the second cladding layer, and at least a portion of the second electrode layer is exposed from the capping layer.

17. A method for fabricating an optical device, comprising:
providing a semiconductor stack structure, wherein the semiconductor stack structure is configured to generate a laser beam when receiving a current and emit the laser beam from a front facet of the semiconductor stack structure, and the front facet is a lateral side of the semiconductor stack structure; and
coating a first dielectric film on the front facet and a rear facet of the semiconductor stack structure, wherein a refractive index of the first dielectric film is greater than about 2, and the rear facet is another lateral side of the semiconductor stack structure.

18. The method according to claim 17, further comprising:
coating a second dielectric film on a surface of the first dielectric film, wherein a refractive index of the second dielectric film is approximately greater than about 1.4; and
coating another first dielectric film on a surface of the second dielectric film.

19. The method according to claim 17, further comprising:
coating a third dielectric film on a top facet of the semiconductor stack structure, wherein a refractive index of the third dielectric film is greater than about 1.4.

20. The method according to claim 19, further comprising:
coating a fourth dielectric film on the third dielectric film, wherein a refractive index of the fourth dielectric film is different from the refractive index of the third dielectric film, and the refractive index of the fourth dielectric film is greater than about 1.4.
